(19) United States
(12) Patent Application Publication
(10) Pub. No.: US 2026/0037708 A1
(43) Pub. Date: Feb. 5, 2026

(54) METHOD AND APPARATUS FOR OPTIMIZING SLOT ALLOCATION OF WAFERS IN BATCH EQUIPMENT OF SEMICONDUCTOR MANUFACTURING PROCESS

(71) Applicant: SAMSUNG ELECTRONICS CO., LTD., Suwon-si (KR)

(72) Inventors: Seungyoon KIM, Suwon-si (KR); Hoyun JUNG, Suwon-si (KR); Jongik HONG, Suwon-si (KR); Byungyong CHOI, Suwon-si (KR)

(73) Assignee: SAMSUNG ELECTRONICS CO., LTD., Suwon-si (KR)

(21) Appl. No.: 19/265,541

(22) Filed: Jul. 10, 2025

(30) Foreign Application Priority Data
Aug. 2, 2024 (KR) 10-2024-0103350
Dec. 17, 2024 (KR) 10-2024-0189074

(51) Int. Cl. G06F 30/337; G06N 3/092

(52) U.S. Cl. CPC G06F 30/337; G06N 3/092

(57) ABSTRACT

A method of optimizing a slot allocation of a wafer in batch equipment of a semiconductor manufacturing process is provided. The method includes loading wafer-specific characteristic data and slot allocation history data, training a reinforcement learning model by using the wafer-specific characteristic data and the slot allocation history data, executing an optimization algorithm for determining a wafer-specific optimum slot location, based on the reinforcement learning model; based on a time for executing the optimization algorithm satisfying a system requirement time, selecting the optimization algorithm as a final algorithm, and allocating a wafer-specific slot in the batch equipment in a next process by using the final algorithm.

### CROSS-REFERENCE TO RELATED APPLICATION(S)

This application is based on and claims priority to Korean Patent Application Nos. 10-2024-0103350, filed on Aug. 2, 2024, and 10-2024-0189074, filed on Dec. 17, 2024 in the Korean Intellectual Property Office, the disclosures of which are herein incorporated by reference in their entireties.

### BACKGROUND

### 1. Field

The disclosure relates to a method and an apparatus for optimizing a wafer-specific slot location in batch equipment, and more particularly, to a method and an apparatus for optimizing a wafer-specific slot location to minimize a defect rate in a semiconductor manufacturing process.

### 2. Description of Related Art

A semiconductor manufacturing process involves a series of operations to form a microscopic structure on a wafer. Equipment used in this manufacturing process may be divided into single wafer equipment and batch equipment. The batch equipment is designed for simultaneously processing a plurality of wafers, and is used for increasing process efficiency and production amount. The batch equipment is utilized in a particular process operation, such as a high temperature heat treatment process operation, a chemical vapor deposition operation, an oxidation process operation, and/or a nitriding process operation.

The batch equipment may decrease process time and increase efficiency of process resources by simultaneously processing a plurality of wafers, but deviation in quality of the wafer may occur. Particularly, according to an arrangement of the wafer in the equipment, quality deviation of process result may occur and a defect rate of the wafer may be determined. However, finding an optimum wafer batch in the equipment is a very complicated issue, and a combination of many variables needs to be considered. Accordingly, research is underway to increase efficiency of the batch equipment, increase precision of process control, and decrease quality deviation of wafer processing.

### SUMMARY

One or more example embodiments of the disclosure may provide a method and an apparatus for minimizing a defect rate of a wafer by controlling a slot location of a wafer in a semiconductor batch equipment of a semiconductor manufacturing process.

One or more example embodiments of the disclosure may provide a method and an apparatus for optimizing a slot location of a wafer for each process by using a reinforcement learning and optimization algorithm.

In addition, the issues to be solved by the technical idea of the disclosure are not limited to those mentioned above, and other issues may be clearly understood by those of ordinary skill in the art from the following descriptions.

According to an aspect of an example embodiment of the disclosure, there is provided a method of optimizing a slot allocation of a wafer in a batch equipment of a semiconductor manufacturing process, the method including: loading wafer-specific characteristic data and slot allocation history data; training a reinforcement learning model by using the wafer-specific characteristic data and the slot allocation history data; executing an optimization algorithm for determining a wafer-specific optimum slot location, based on the reinforcement learning model; selecting, based on a time for executing the optimization algorithm satisfying a system requirement time, the optimization algorithm as a final algorithm; and allocating a wafer-specific slot in the batch equipment in a next process of the semiconductor manufacturing process, by using the final algorithm.

According to an aspect of an example embodiment of the disclosure, there is provided a method of optimizing a slot allocation of a wafer in a batch equipment of a semiconductor manufacturing process, the method including: loading wafer-specific characteristic data and slot allocation history data; grouping, in zone units, slots having similar process results of wafers according to a characteristic of the batch equipment; training a reinforcement learning model by limiting an action space to a number of slots included in a zone, and by using the wafer-specific characteristic data and the slot allocation history data;

executing an optimization algorithm for determining a wafer-specific optimum slot location, based on the reinforcement learning model; selecting, based on a time for executing the optimization algorithm satisfying a system requirement time, the optimization algorithm as a final algorithm; and allocating a wafer-specific slot in the batch equipment in a next operation of the semiconductor manufacturing process, by using the final algorithm.

According to an aspect of an example embodiment of the disclosure, there is provided an electronic device including a memory storing at least one instruction, and at least one processor configured to execute the at least one instruction stored in the memory to perform: train a reinforcement learning model by using wafer-specific characteristic data and slot allocation history data; execute an optimization algorithm for determining a wafer-specific optimum slot location, based on the reinforcement learning model; select, based on a time for executing the optimization algorithm satisfying a system requirement time, the optimization algorithm as a final algorithm; and by using the final algorithm, allocate a wafer-specific slot in batch equipment in a next process of a semiconductor manufacturing process.

### BRIEF DESCRIPTION OF DRAWINGS

Example embodiments will be more clearly understood from the following detailed description taken in conjunction with the accompanying drawings in which:

FIG. 1A is a block diagram illustrating batch equipment according to one or more embodiments;

FIGS. 1B through 1E are views for describing a processing chamber of batch equipment, according to one or more embodiments;

FIG. 2 is a schematic flowchart of a method of optimizing slot allocation of a wafer in batch equipment of a semiconductor manufacturing process, according to one or more embodiments;

FIG. 3 is a schematic flowchart of an example sequence of a semiconductor manufacturing process using batch equipment, according to one or more embodiments;

FIG. 4 is a table of data that may be used in training of a reinforcement learning model for optimizing slot allocation of a wafer in batch equipment for each process of a semiconductor manufacturing process, according to one or more embodiments;

FIG. 5 is a conceptual diagram of reinforcement learning that may be used in one or more embodiments;

FIG. 6 is a schematic flowchart of a method of executing an optimization algorithm for determining an optimum slot location, according to one or more embodiments;

FIG. 7 is an example diagram of a process result according to a slot location and grouping slots in zone units according to a process result, in a particular process operation of a semiconductor manufacturing process, according to one or more embodiments;

FIG. 8 is a schematic flowchart of a method of optimizing slot allocation of a wafer in batch equipment of semiconductor manufacturing process, according to one or more embodiments;

FIG. 9 is a schematic flowchart of a method of optimizing processing space allocation of a wafer lot in batch equipment of semiconductor manufacturing process, according to one or more embodiments; and

FIG. 10 is a schematic diagram of an electronic device according to one or more embodiments.

### DETAILED DESCRIPTION

Hereinafter, example embodiments of the disclosure will be described in detail with reference to the accompanying drawings. Identical reference numerals are used for the same constituent elements in the drawings, and duplicate descriptions thereof are omitted. In addition, one of ordinary skill would understand that aspects of some embodiments may be combined together or implemented alone.

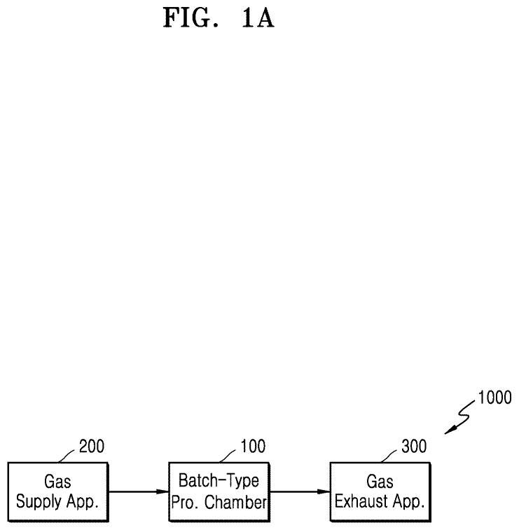

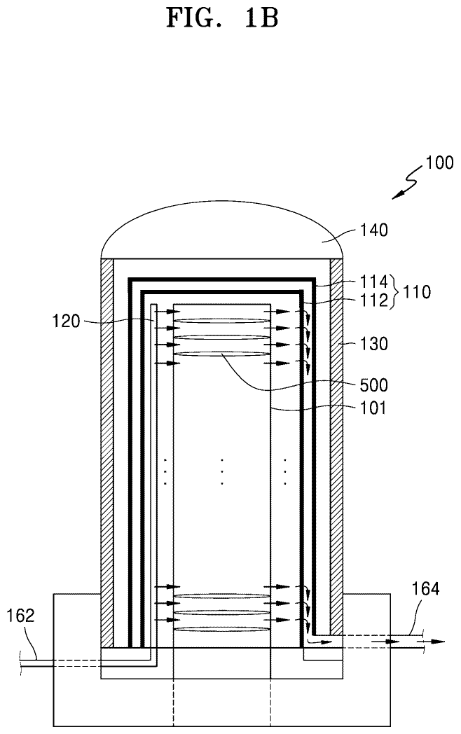

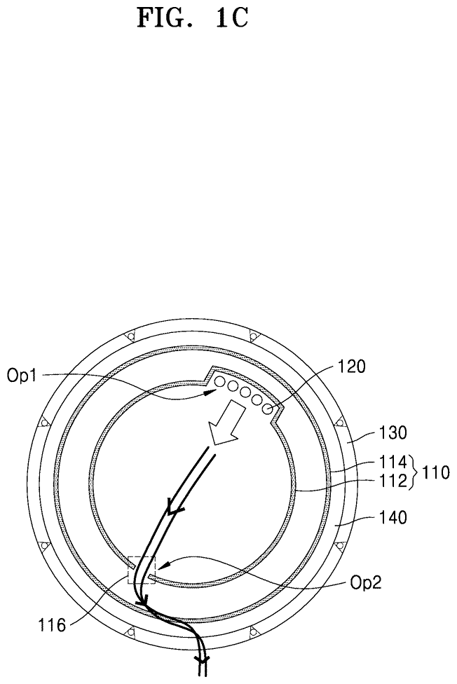

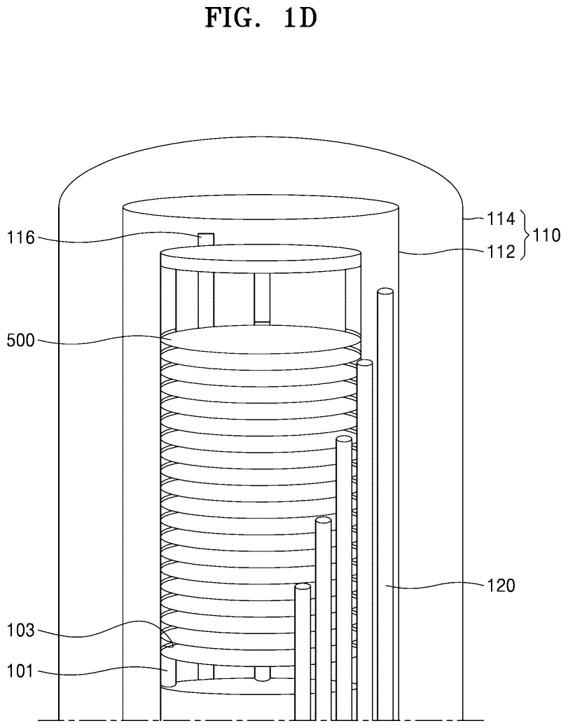

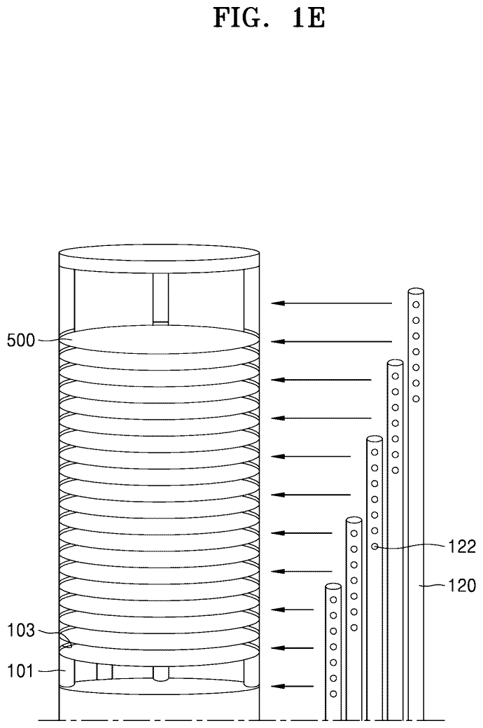

FIG. 1A is a block diagram illustrating batch equipment according to one or more embodiments, and FIGS. 1B through 1E are views for describing a processing chamber of batch equipment, according to one or more embodiments.

Referring to FIGS. 1A through 1E, batch equipment 1000 of a semiconductor manufacturing process according to an embodiment may include a batch-type processing chamber 100, a gas supply apparatus 200, and a gas exhaust apparatus 300.

The batch-type processing chamber 100 may include, as a chamber of a batch type, a device capable of simultaneously performing a process operation such as a deposition operation on a plurality of wafers 500. Hereinafter, the batch-type processing chamber 100 may be briefly referred to as the processing chamber 100. The processing chamber 100 may include a wafer stacking container 101, a process tube 110, a nozzle 120, a heater 130, and a chamber cover 140.

The wafer stacking container 101 may be used to stack the plurality of wafers 500 in a vertical direction. The wafer stacking container 101 may include a plurality of slots 103, and each slot may be accommodate a wafer. For example, as illustrated in FIG. 1D, in the wafer stacking container 101, the plurality of slots 103 may be apart from each other in the vertical direction, and the plurality of wafers 500 may be arranged in the plurality of slots 103.

The process tube 110 may include a vertical process tube, which may have a cylindrical tube shape and expand in the vertical direction. For example, the process tube 110 may include an inner tube 112 and an outer tube 114. The inner tube 112 may have a cylindrical tube shape that expands in the vertical direction and include an upper end thereof that is closed. A processing space may be provided in the inner tube 112. Accordingly, as illustrated in FIG. 1B or 1D, the wafer stacking container 101 may be inserted in the processing space of the inner tube 112 and seated therein. Although not illustrated, the process tube 110 may include a standby room at a lower end portion of the inner tube 112, and the wafer stacking container 101 may be pushed into the standby room from an outside of the process tube 110, and may move to the inner tube 112 to be accommodated in the processing space of the inner tube 112.

The outer tube 114 may have a shape surrounding the inner tube 112. For example, the outer tube 114 may have a cylindrical tube shape that expands in the vertical direction and includes an upper end thereof closed. On the other hand, when process gas is injected into the inner tube 112 via the nozzle 120, and exhaust gas is exhausted via a gas outlet 116 of the inner tube 112, the exhaust gas may be exhausted through a space between the inner tube 112 and the outer tube 114. According to some embodiments, the outer tube 114 may be omitted. For example, the process tube 110 may include only the inner tube 112 without the outer tube 114, and the heater 130 and the chamber cover 140 may directly surround the inner tube 112.

The nozzle 120 may supply the process gas to the wafer 500. For example, the nozzle 120 may be arranged on a first outer portion Op1 inside the inner tube 112. In this case, the first outer portion Op1 may have a relative concept with respect to a second outer portion Op2 adjacent to a portion of the inner tube 112 on which the gas outlet 116 is provided. The gas outlet 116 may be provided in a portion of the inner tube 112 corresponding the second outer portion Op2. However, an arrangement of the nozzle 120 is not limited thereto.

The nozzle 120 may have a pipe pillar shape expanding in the vertical direction. In addition, multiple gas injection holes (refer to 122 in FIG. 1E) may be provided on a side surface of the nozzle 120. The process gas may be injected into the inner tube 112 via the gas injection hole 122 and may be supplied onto the wafer 500.

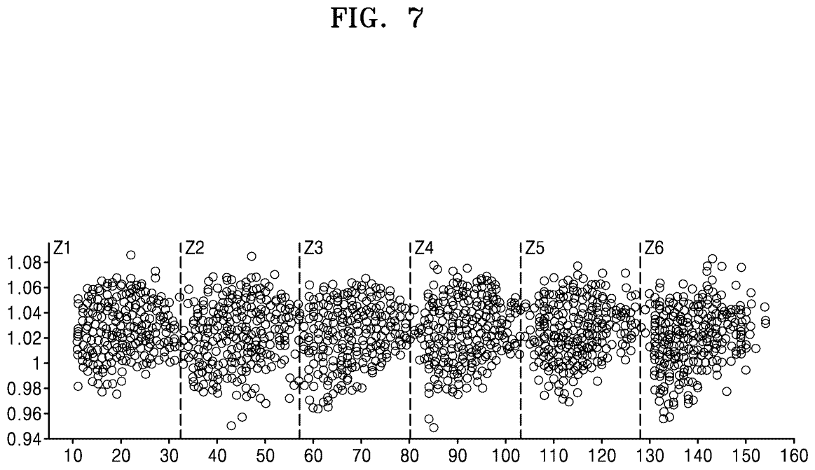

The nozzle 120 may be arranged in plural inside the inner tube 112. For example, a plurality of nozzles 120 may have different heights. The plurality of nozzles 120 may be arranged at different heights and inject the gas evenly on the wafers 500 in the wafer stacking container 101. When the plurality of nozzles 120 having different heights in this manner are arranged, there is a tendency in process results of the wafers 500 according to locations of the slots 103 of the wafers 500. This will be described in more detail later with reference to FIG. 7.

The heater 130 may have a shape surrounding the process tube 110. Accordingly, the heater 130 may have a cylindrical tube shape similar to that of the process tube 110. The heater 130 may heat an inside of the inner tube 112 and the wafer 500 to a proper temperature.

The chamber cover 140 may cover an upper portion of the processing chamber 100. According to an embodiment, the heater 130 may be provided inside the chamber cover 140. The chamber cover 140 may heat an upper space inside the inner tube 112 by using the heater 130.

The gas supply apparatus 200 may supply the process gas to the processing chamber 100. The process gas may be supplied from the gas supply apparatus 200 into the inner tube 112 via a supply pipe 162 and the nozzle 120.

The gas exhaust apparatus 300 may exhaust the exhaust gas remaining the processing chamber 100 after a process operation is performed. For example, the exhaust gas from the inner tube 112 may be transferred to the gas exhaust apparatus 300 via a path between the inner tube 112 and the outer tube 114 and via an exhaust pipe 164, and may be exhausted to an outside via the gas exhaust apparatus 300.

A structure of the batch equipment 1000 capable of simultaneously processing the plurality of wafers 500 described with reference to FIGS. 1A through 1E is only an example, and the structure and components thereof may be variously changed.

Hereinafter, for convenience, allocating locations of the slots 103 of the wafers 500 inside the processing chamber 100 of the batch equipment 1000 capable of simultaneously processing the plurality of wafers 500 is referred to as allocating the slot of the wafer inside the batch equipment.

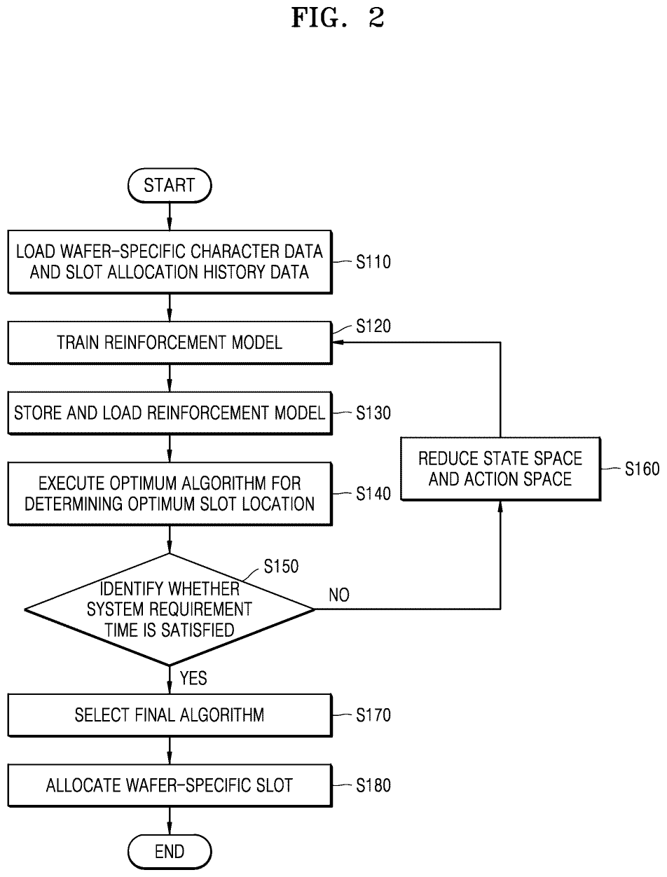

FIG. 2 is a schematic flowchart of a method of optimizing slot allocation of a wafer in batch equipment of a semiconductor manufacturing process, according to one or more embodiments.

Referring to FIG. 2, a method of optimizing slot allocation of a wafer in batch equipment of a semiconductor manufacturing process according to one or more embodiments may include loading wafer-specific characteristic data and slot allocation history data (S110), training a reinforcement learning model by using the wafer-specific characteristic data and the slot allocation history data (S120), storing and loading the reinforcement learning model (S130), executing an optimization algorithm for determining a wafer-specific optimum slot location that minimizes a defect rate, based on the reinforcement learning model (S140), determining whether a time for executing the optimization algorithm satisfies a system requirement time (S150), selecting the optimization algorithm as a final algorithm if the system requirement time is satisfied (S170), and allocating wafer-specific slots in the batch equipment in a next process operation by using the final algorithm (S180).

Firstly, in operation S110, wafer-specific characteristic data and slot allocation history data may be loaded. During a series of semiconductor manufacturing processes, a defect in a wafer in a particular process may be affected by a characteristic of the wafer itself and a history of one or more previous processes (hereinafter referred to as ‘previous process’). Accordingly, an operation of acquiring wafer-specific characteristic data and slot allocation history data that may affect an occurrence of a wafer defect and an operation of loading the same may be performed.

For example, in an oxide-nitride-oxide passivation (ONOP) process for forming a dielectric layer for a cell operation of a semiconductor device on a wafer, a defect in the wafer in a deposition process may be determined by a hole profile shape formed on the wafer, a layer thickness formed during the deposition process, and a layer concentration formed in the deposition process. In this case, the hole profile shape may correspond to wafer-specific characteristic data for each wafer. According to an embodiment, the wafer-specific characteristic data may include optical emission spectrometer (OES) data, measurement data, such as optical critical dimension (OCD) and critical dimension (CD), or virtual metrology (VM) data.

As described with reference to FIGS. 1A through 1E, batch equipment according to one or more embodiments may include a plurality of nozzles, and each nozzle may include a plurality of gas injection holes. Deviation in gas supply to wafers according to corresponding slot locations may occur due to arrangements of the nozzles and the gas injection holes. Alternatively, a difference in a reaction speed according to corresponding slot locations may occur due to a temperature difference in the batch equipment. When a previous process has been performed in the batch equipment, that each wafer has been arranged at which slot in the previous process (or slot location history) may be a factor to affect the layer thickness and the layer concentration. Accordingly, the layer thickness and the layer concentration may be determined by the slot location history of a wafer in the previous process and a slot location of the wafer in a current process. In other words, the slot location of the wafer in the current process may be an optimization target to be determined for controlling a defect occurrence (or defect rate) of the wafer, and wafer-specific characteristic data including a hole profile shape and slot allocation history data of a wafer in the previous process may be variables to be used for optimization.

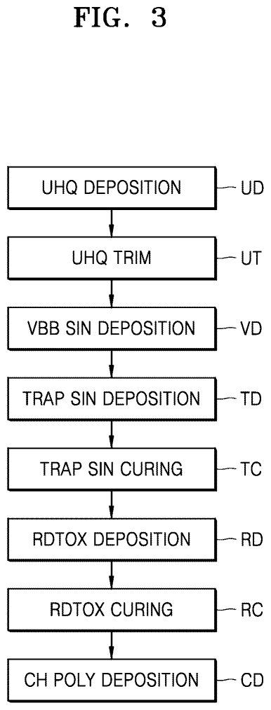

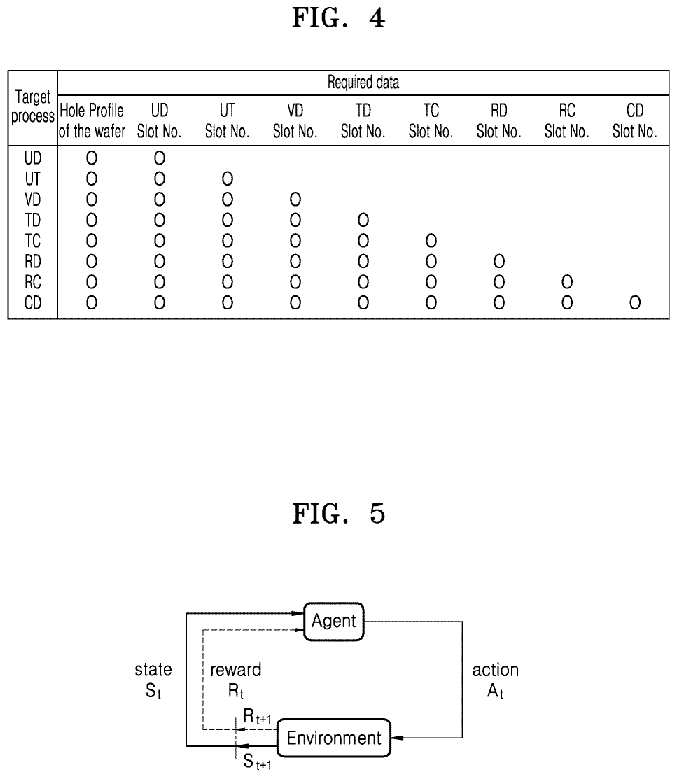

FIG. 3 is a schematic flowchart of an example sequence of a semiconductor manufacturing process using batch equipment, according to one or more embodiments. FIG. 4 is a table of data that may be used in training of a reinforcement learning model for optimizing slot allocation of a wafer in the batch equipment for each process of the semiconductor manufacturing process, according to one or more embodiments.

A process of simultaneously processing a plurality of wafers may be performed in the batch equipment. For example, when the ONOP process is performed to form a dielectric layer for a cell operation of a semiconductor device inside a plug on a wafer, a deposition process may be performed after an etching process is performed on the wafer.

Referring to FIG. 3, oxide or nitride may be deposited on a surface of a wafer by using an ultra high quality (UHQ) deposition process UD, and the thickness or quality of the deposited oxide or nitride may be finely adjusted by using a UHQ trim process UT. Thereafter, a voltage breakdown (VBB) silicon nitride (SiN) deposition process VD may be performed. The VBB SiN deposition process VD may be a second silicon deposition process, and may deposit SiN on a wafer surface for the purpose of reinforcing high voltage resistance. A trap SiN deposition process TD may deposit SiN on a wafer for inducing trapping phenomenon of electrons or charges. Thereafter, a trap SiN curing process TC may stabilize a characteristic of SiN by using a high temperature heat treatment and fix the charge trap. By using a rapid thermal oxidation (RDTOX) deposition process RD, a reaction with oxygen or vapor at high temperature may be performed to form an oxide layer on a wafer surface, and by using a RDTOX curing process RC, defects at high temperature may be removed to reinforce an oxide layer. Thereafter, by using a channel (CH) poly-silicon (poly) deposition process CD, a poly layer to be used as an electrode or a gate of a device may be formed. The poly layer may be formed by using, for example, a chemical vapor deposition process.

Referring to FIGS. 2 through 4, for model learning to optimize a slot location of a wafer in the batch equipment in each process, wafer-specific hole profile shape data, wafer-specific slot allocation history data of a previous process performed prior to a current process, and wafer-specific slot allocation data in the current process may be used.

For example, to minimize an occurrence of a wafer defect in the RDTOX deposition process RD, the wafer-specific hole profile shape data, a slot number allocated in the UHQ deposition process UD, a slot number allocated in the UHQ trim process UT, a slot number allocated in the VDD SIN deposition process VD, a slot number allocated in the trap SiN deposition process TD, a slot number allocated in the trap SiN curing process TC, and a slot number allocated in the RDTOX deposition process RD may be used.

As the semiconductor manufacturing process moves to subsequent processes, because a number of variable data, that is, the wafer-specific slot allocation history data increases, a number of possible outcomes (or number of cases) grows exponentially, and it may become difficult to calculate a slot location-specific defect rate of a wafer. Accordingly, in some embodiments, the reinforcement learning model may be trained by using the wafer-specific characteristic data and the slot allocation history data, and the optimization algorithm based on the trained model may be executed to obtain an optimum wafer slot allocation.

The semiconductor manufacturing process described with reference to FIGS. 3 and 4 is only an example, and may describe an example of optimization of a slot location of a wafer in the batch equipment during a series of process operations. Thus, in the batch equipment according to embodiments to be described hereafter, the semiconductor manufacturing process to which the slot allocation optimization of wafers is applied is not limited to the processes described with reference to FIGS. 3 and 4.

Referring to FIG. 2 again, in operation S120, the reinforcement learning model may be trained by using the wafer-specific characteristic data and the slot allocation history data. The reinforcement learning may include a method in which an agent learns an optimum action policy for successfully performing a given task, while interacting with an environment. In the reinforcement learning, the agent may receive a result of action as a reward, and may learn by itself based on the result of action. In this case, the agent may include a subject selecting the action, the environment may include a space in which the agent interacts with the environment, and the reward may mean a feedback that the agent receives from the environment as a result of performing an action. The environment may provide a reward and a new state in response to the action of the agent. In addition, the policy may mean a rule or strategy to determine which action is to be selected in a given state, and a main object of the reinforcement learning may include searching for an optimum policy.

FIG. 5 is a conceptual diagram of reinforcement learning that may be used in one or more embodiments.

Referring to FIG. 5, the agent may, in a present environment, observe a state Sₜ, select an action Aₜ, and based on the selected action Aₜ, receive a reward Rₜ₊₁ and a new state Sₜ₊₁ from the environment. In this case, the state may mean information about observing the present environment. The agent may learn to select an action having a higher possibility of receiving a better reward by updating the policy based on the received reward.

According to some embodiments, as a reinforcement learning model, a value-based algorithm model including Q-Learning, state-action-reward-state-action (SARSA), Deep Q-Network (DQN), Double DQN, Dueling DQN, Noisy DQN, and Rainbow DQN, a policy-based algorithm model including REINFORCE, Actor-Critic, Proximal Policy Optimization (PPO), and Trust Region Policy Optimization (TRPO), and algorithm models combining values and policies including Advantage Actor-Critic (A2C), Asynchronous

Advantage Actor-Critic (A3C), and Soft Q-Learning (SQL) may be used. When an action space is discrete, and a state space and the action space are large, DQN series (Rainbow DQN and Double DQN) or PPO may be used. In particular, Rainbow DQN or PPO may be used in a complex environment, and Q-Learning or DON may be used in a simple environment.

Referring to FIG. 2 again, according to the embodiment, in operation S120, the reinforcement learning model may include a Deep Q-Network model. When the reinforcement learning model is trained, the action may determine slot locations of the wafers in a subsequent process, and may be targeted at minimizing an average defect rate of the wafers. For example, the reward may be defined as a negative value of a defect rate according to the slot location of a wafer. The state may mean information about the slot location for each wafer in the previous process.

The reinforcement learning model may update the network by using empirical replay based on the wafer-specific characteristic data and the slot allocation history data obtained in operation S110. For example, an epsilon (ε)—greedy policy may be used in selecting an action to determine the slot location of a wafer. The ε-greedy policy may include an action selection strategy for adjusting a balance between exploration and exploitation in the reinforcement learning. The exploration may include searching for new possibility by selecting random actions, and the exploitation may include selection of an action expected to provide a highest reward from a policy or a value function trained up to a present time point. The action may be selected by selecting the exploration at probability ε, and selecting the exploitation at probability (1−ε).

In operation S130, the reinforcement learning model may be stored and loaded. In operation S130, the reinforcement learning model that is trained in operation S120 may be stored and when needed, may be loaded. For example, the trained DQN model may be stored, and when needed, may be loaded to be used.

In operation S140, the optimization algorithm for determining the wafer-specific optimum slot location that minimizes the defect rate, based on the reinforcement learning model, may be executed. According to an embodiment, the optimization algorithm may include a genetic algorithm and/or a greedy algorithm, but the disclosure is not limited thereto.

The genetic algorithm may include a genetic optimization algorithm for searching for an optimum solution by imitating an evolution process in the nature, and may be used in searching for a global optimum solution for mainly complex issues. In the genetic algorithm, possible solutions may be expressed in individuals or chromosomes, and as a result of performing simulation of survival competition in a population including several individuals, individuals having a high fitness may have a high chance of survival, and may generate a new generation by using genetic crossover and mutation. The genetic algorithm may include an algorithm in which generations are repeated to find a gradually better solution.

The genetic algorithm may randomly generate an initial group, calculate a fitness of each individual within the group, and select an individual with a high fitness as a parent. In this case, as a selection technique, one of roulette wheel selection for providing a selection probability in proportion to the fitness, rank selection for choosing a selection in proportion to a fitness rank, and tournament selection for choosing a selection of an individual having the highest fitness among randomly selected individuals, or the like may be used. In generating new offspring by using the crossover that combines selected parent individuals, genetic information of two individuals may be combined to generate a next generation, and in this case, diversity may be added by using mutation that randomly modifies genes of the offspring. In this manner, a new group may be generated by using selection, crossover, and mutation, and the algorithm may be terminated when a termination condition such as reaching a particular generation number and/or reaching a certain level of fitness, is satisfied.

When the optimum wafer slot location is determined by using the genetic algorithm, a method of avoiding duplication during the crossover and mutation processes may need to be added such that one wafer is assigned to one slot. For example, when generating a child individual, to prevent duplication during the crossover calculation, values of the parent may need to be checked such that new values are not duplicated during the mutation calculation.

The genetic algorithm may have a high probability of getting an answer close to a global optimal solution, but may require relatively many calculations and thus an inference speed thereof may be slow.

The greedy algorithm may include a method of finding a final solution by iterating a most optimum choice in a present state. Because the greedy algorithm takes the optimum selection at every operation, the greedy algorithm may require relatively less calculations and has a fast inference speed, but it may be highly possible that the greedy algorithm selects a local optimal solution rather than the global optimal solution that minimizes the average defect rate of the entire wafers, which is the target of optimization.

In this manner, in operation S140 of executing the optimization algorithm, there may be a trade-off between obtaining a solution close to the global optimum solution according to the optimization algorithm and a time for executing the optimization algorithm. Accordingly, in operation S140, only one optimization algorithm may be selectively executed among a plurality of optimization algorithms, or one optimization algorithm that satisfies one or more criterions may be determined by executing the plurality of optimization algorithms.

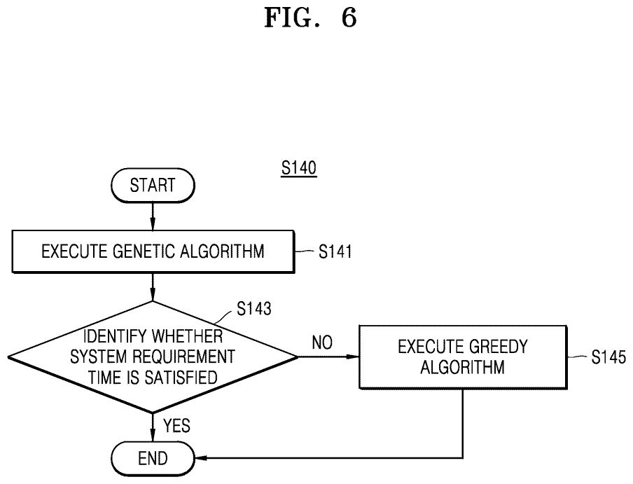

FIG. 6 is a schematic flowchart of a method of executing the optimization algorithm for determining the optimum slot location, according to one or more embodiments.

Referring to FIG. 6, in operation S140 of executing the optimization algorithm, first, operation S141 of executing the genetic algorithm may be performed, and whether time for executing the genetic algorithm satisfies the system requirement time may be determined in operation S143, and when this condition is satisfied, operation S140 may be terminated. When the time for executing the genetic algorithm does not satisfy the system requirement time, that is, when the time for executing the genetic algorithm exceeds the system requirement time, operation S145 of executing the greedy algorithm may be performed and then operation S140 may be terminated.

As an example of the optimization algorithm, only the genetic algorithm and the greedy algorithm are described, but the disclosure is not limited thereto, and in operation S140, other various types of optimization algorithm may be used.

Referring to FIG. 2 again, whether the time for executing the optimization algorithm satisfies the system requirement time may be identified in operation S150, and when satisfied (for example, the time for executing the optimization algorithm is equal to or less than the system requirement time), the optimization algorithm may be selected as the final algorithm in operation S170. By using the selected final algorithm, the wafer-specific slot may be allocated in the batch equipment in the subsequent process in operation S180.

Whether the time for executing the optimization algorithm satisfies the system requirement time is identified in operation S150, and when not satisfied (for example, when the time for executing the optimization algorithm exceeds the system requirement time), operation S160 of reducing the state space and the action space of the reinforcement learning model may be performed.

According to the embodiment, in operation S160, the state space and the action space may be reduced by using domain knowledge of the batch equipment.

FIG. 7 is an example diagram of a process result according to a slot location and grouping slots in zone units according to the process result, in a particular process operation of the semiconductor manufacturing process, according to one or more embodiments. In FIG. 7, a horizontal axis may represent the slot location of the batch equipment, and a vertical axis may represent eDimple in which the hole of the wafer is concave.

Referring to FIG. 7, it may be identified that a pattern of eDimple is repeated approximately in units of 20 slots. As described with reference to FIGS. 1A through 1E, the plurality of nozzles in the batch equipment may have different heights that are different in a certain interval. For example, when a dummy wafer is arranged at a certain vulnerable location in the batch equipment, hardware equivalence may occur, and the pattern of the wafer may be repeated after the process for each slot unit in the batch equipment.

When the pattern of the wafer is repeated as the process result for each slot unit, slots having similar process results of wafers may be grouped in zone units, and the state space and the action space of the reinforcement learning model may be reduced. For example, when six zones are grouped as illustrated in FIG. 7, a first slot of first zone Z1 may be regarded as the same (or substantially the same) as first slots of second through sixth zones Z2 through Z6. Accordingly, the state space may be reduced to a number of slots included in each zone. A type of an action may be limited to the number of slots included in one zone to reduce the action space. Accordingly, an amount of computation may be reduced by allowing duplication of the action to six times corresponding to the number of zones.

Furthermore, when the process result has symmetry in each zone, the state space and the action space may be further reduced by using the symmetry. For example, when there is the symmetry of the process result with respect to a slot at a center in each zone in FIG. 7, the state space and the action space may be reduced to half.

Referring to FIG. 2 again, in the state space and the action space reduced in operation S160, the training of the reinforcement learning model by using the wafer-specific characteristic data and the slot allocation history data (S120), the storing and loading of the reinforcement learning model (S130), the executing of the optimization algorithm for determining the wafer-specific optimum slot location that minimizes the defect rate, based on the reinforcement learning model (S140), and the determining of whether the time for executing the optimization algorithm satisfies the system requirement time of the system (S150) may be sequentially performed again.

When the time for executing the optimization algorithm corresponds to be equal to or less than the system requirement time of the system in operation (S150), the optimization algorithm may be selected as the final algorithm (S170), and by using the selected final algorithm, wafer-specific slots in the batch equipment may be allocated in a following process operation (S180).

According to an embodiment, in operation S160, the state space and the action space may be firstly reduced according to grouped zones of slots and operations S120 to S140 may be performed. However, when the time for executing the optimization algorithm exceeds the system requirement time in operation S150, the state space and the action space may be again reduced by using the symmetry in operation S160, and operations S120 to S140 may be performed.

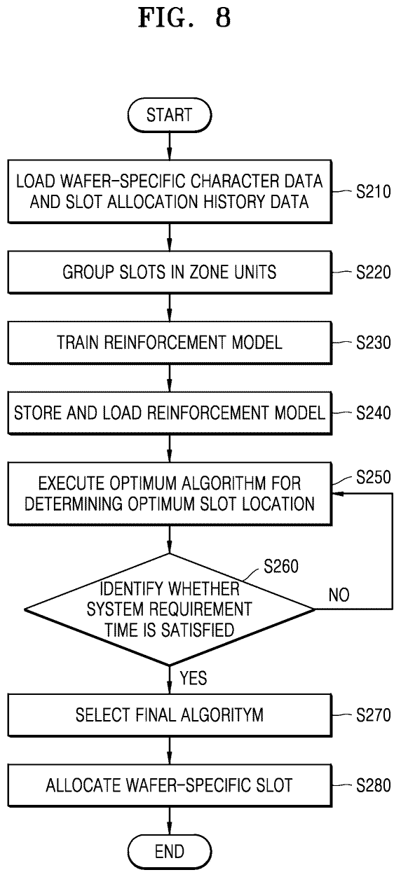

FIG. 8 is a schematic flowchart of a method of optimizing slot allocation of a wafer in the batch equipment of the semiconductor manufacturing process, according to one or more embodiments. The method of optimizing the slot allocation of a wafer in the batch equipment of the semiconductor manufacturing process described with reference to FIG. 8 is generally the same as or similar to the method of optimizing the slot allocation of the wafer described with reference to FIGS. 2 through 7. Accordingly, for convenience of description, the difference between the method of optimizing the slot allocation of the wafer in FIG. 8 and the method in FIG. 2 is mainly described.

Referring to FIG. 8, the method of optimizing the slot allocation of a wafer in the batch equipment of the semiconductor manufacturing process according to an embodiment may include loading the wafer-specific characteristic data and the slot allocation history data (S210), grouping the slots in zone units (S220), training the reinforcement learning model by using the wafer-specific characteristic data and the slot allocation history data (S230), storing and loading the reinforcement learning model (S240), executing the optimization algorithm for determining the wafer-specific optimum slot location that minimizes the defect rate, based on the reinforcement learning model (S250), determining whether the time for executing the optimization algorithm satisfies the system requirement time (S260), selecting the optimization algorithm as the final algorithm if the system requirement time is satisfied (S270), and allocating the wafer-specific slot in the batch equipment in the next process operation by using the final algorithm (S280).

Operation S210 may be substantially the same as operation S110 in FIG. 2.

In operation S220, that is, in a particular process operation of the

semiconductor manufacturing process according to the embodiment, the slots having similar process results of wafers may be grouped in zone units. Operation S220 may be substantially the same as operation S160 described in the descriptions given with reference to FIGS. 2 and 7. However, unlike the method of FIG. 2, in the method of FIG. 8, the state space and the action space may be reduced according to a zone unit in advance before the reinforcement learning model is trained.

In operation S230, in the state space and the action space, which are reduced by grouping the slots in a zone unit, the reinforcement learning model may be trained. For example, the DQN model may be used as the reinforcement learning model.

In operation S240, the trained reinforcement learning model may be stored and loaded.

In operation S250, the optimization algorithm for determining the wafer-specific optimum slot location that minimizes the defect rate, based on the reinforcement learning model may be executed. According to an embodiment, the optimization algorithm may include a genetic algorithm and/or a greedy algorithm, but the disclosure is not limited thereto. In operation S250, only one optimization algorithm may be selectively executed, or one optimization algorithm that satisfies the criteria may be determined by executing a plurality of optimization algorithms.

In operation S260, whether the time for executing the optimization algorithm satisfies the system requirement time may be identified, and when not satisfied (for example, when the time for executing the optimization algorithm exceeds the system requirement time), the method may return to operation S250 again to execute another optimization algorithm. For example, when the operation S250 and operation S260 are performed, the genetic algorithm may be firstly performed according to the method described with reference to FIG. 6, and when the time for executing the genetic algorithm does not satisfy the system requirement time, the greedy algorithm may be performed.

In operation S270, the final algorithm may be selected, and by using the final algorithm selected in operation S280, the wafer-specific slot in the batch equipment may be allocated in the next process operation.

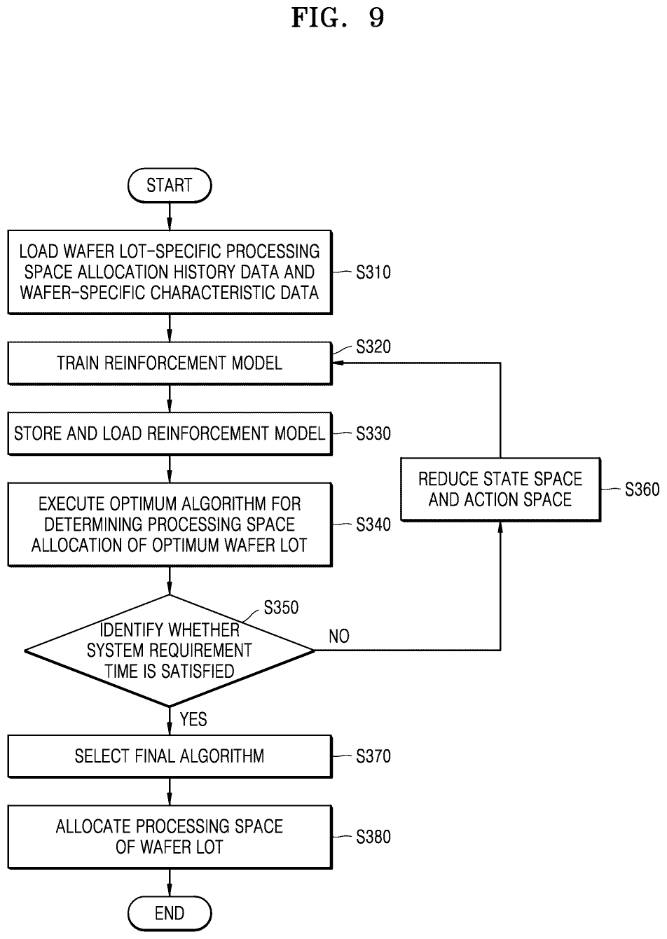

FIG. 9 is a schematic flowchart of a method of optimizing processing space allocation of a wafer lot in the batch equipment of the semiconductor manufacturing process, according to one or more embodiments. The method of optimizing the processing space allocation of a wafer lot in the batch equipment described with reference to FIG. 9 may be similar to the method of optimizing the slot allocation of a wafer in the batch equipment in FIG. 2, except that a processing space for the wafer lot including a plurality of wafers is allocated rather than allocating a slot for each wafer.

Referring to FIG. 9, the method of optimizing the processing space allocation of the wafer lot in the batch equipment of the semiconductor manufacturing process according to an embodiment may include loading wafer lot-specific processing space allocation history data and wafer-specific characteristic data (S310), training the reinforcement learning model by using the wafer lot-specific processing space allocation history data and the wafer-specific characteristic data (S320), storing and loading the reinforcement learning model (S330), executing the optimization algorithm for determining a wafer lot-specific optimum processing space allocation to minimize the defect rate, based on the reinforcement learning model (S340), determining whether the time for executing the optimization algorithm satisfies the system requirement time (S350), selecting the optimization algorithm as the final algorithm if the system requirement time is satisfied (S370), and allocating the wafer lot-specific processing space in the batch equipment in the next process operation by using the final algorithm (S380).

Operation S310 may be similar to operation S110 in FIG. 2, but instead of loading history data (or slot allocation history data) of allocating a wafer-specific slot in the batch equipment, history data of allocating a wafer lot-specific processing space may be loaded along with characteristic data of each wafer. In this case, the wafer lot may mean a combination of wafers to be processed in the semiconductor process operation, and several wafers may be processed as a group. For example, one wafer lot may include 24 or 25 wafers.

In operation S320, the reinforcement learning model may be trained by using the wafer lot-specific processing space allocation history data and the wafer-specific characteristic data. In this case, the action may determine processing space arrangement of the wafer lots in the next process, and may minimize an average defect rate of wafers as the target. In addition, the reward may be defined as a negative value of the defect rate of the wafers according to the processing space arrangement of the wafer lots. The state may mean information about the processing space arrangement in the previous process for each wafer lot. According to some embodiments, the reinforcement learning model may include a DQN model.

In operation S330, the trained reinforcement learning model may be stored and loaded.

In operation S340, the optimization algorithm for determining the wafer lot-specific optimum processing space arrangement that minimizes the defect rate, based on the reinforcement learning model, may be executed. According to an embodiment, the optimization algorithm may include a genetic algorithm and/or a greedy algorithm, but the disclosure is not limited thereto. In operation S340, only one optimization algorithm may be selectively executed, or one optimization algorithm that satisfies the criteria may be determined by executing a plurality of optimization algorithms.

In operation S350, whether the time for executing the optimization algorithm satisfies the system requirement time may be identified, and when satisfied (for example, the time for executing the optimization algorithm is equal to or less than the system requirement time), the optimization algorithm may be selected as the final algorithm in operation S370. By using the selected final algorithm, the wafer lot-specific processing space may be allocated in the batch equipment in the subsequent process in operation S380.

When the time for executing the optimization algorithm satisfies the system requirement time is identified in operation S350, and when not satisfied (for example, when the time for executing the optimization algorithm exceeds the system requirement time), operation S360 of reducing the state space and the action space of the reinforcement learning model may be performed. In operation S360, the wafer lot according to the process result according to an arrangement of the wafer lot may be grouped in a zone unit, and the state space and the action space may be reduced.

In the state space and the action space reduced in operation S360, learning the reinforcement learning model by using the wafer lot-specific processing space allocation history data and the wafer-specific characteristic data (S320), storing and loading the reinforcement learning model (S330), executing the optimization algorithm for determining the wafer lot-specific optimum processing space allocation to minimize the defect rate, based on the reinforcement learning model (S340) may be sequentially performed again.

Thereafter, in operation S350, whether the time for executing the optimization algorithm satisfies the system requirement time may be identified, and when satisfies (for example, when the time for executing the optimization algorithm is equal to or less than the system requirement time), the optimization algorithm may be selected as the final algorithm (S370), and the wafer lot-specific processing space in the batch equipment in the next process operation may be allocated by using the selected final algorithm (S380).

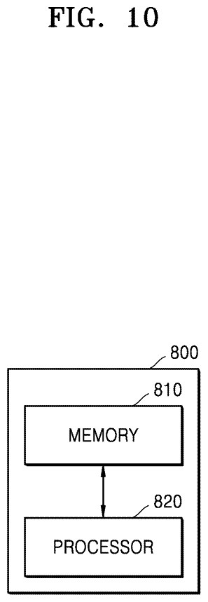

FIG. 10 is a schematic diagram of an electronic device 800 according to one or more embodiments.

Referring to FIG. 10, the electronic device 800 according to an embodiment may include a memory 810, and one or more processors (hereinafter referred to as ‘processor’) 820. The memory 810 may store computer-readable instructions. When instructions stored in the memory 810 are executed by the processor 820, the processor 820 may process operations defined by the instructions. The memory 810 may include, for example, a random access memory (RAM), a dynamic RAM (DRAM), a static RAM (SRAM), or any other type of a non-volatile memory. The memory 810 may store a pre- trained reinforcement learning model.

One or more processors 820 according to an embodiment may control an overall operation of the electronic device 800. The processor 820 may be implemented in hardware that includes circuitry having a physical structure for performing desired operations. The desired operations may include code or instructions included in a program. A hardware-implemented processor 820 may include a microprocessor, a central processing unit (CPU), a graphics processing unit (GPU), a processor core, a multi-core processor, a multiprocessor, an application-specific integrated circuit (ASIC), a field programmable gate array (FPGA), a natural processing unit (NPU), etc.

The processor 820 according to the embodiment may perform the method of optimizing a slot allocation of a wafer in the batch equipment of the semiconductor manufacturing process described above with reference to FIGS. 1A through 8. For example, the processor 820 may train the reinforcement learning model by using the wafer-specific characteristic data and the slot allocation history data, and execute the optimization algorithm to determine the wafer-specific optimum slot location that minimizes the defect rate, based on the learned reinforcement learning model. According to an embodiment, the optimization algorithm may include the genetic algorithm and/or the greedy algorithm, but the disclosure is not limited thereto.

According to an embodiment, the processor 820 may train the reinforcement learning model and execute an optimization algorithm, such that an action is determined for minimizing the average defect rate of the wafers by determining the slot locations of the wafers. In addition, the processor 820 may determine the slot locations of the wafers by applying a constraint that does not allow duplication of slot allocation when executing the optimization algorithm. When the time for executing the optimization algorithm satisfies the system requirement time, the processor 820 may select the corresponding optimization algorithm as the final algorithm. In this case, the processor 820 may select the final algorithm in consideration of a balance between the calculation speed of the optimization algorithm and the fitness of the solution. The processor 820 may allocate the wafer-specific slot in the batch equipment in the next process operation by using the final algorithm.

According to some embodiments, when time for executing optimization algorithm does not satisfy system requirement time, the processor 820 may group slots, having similar process results of wafers according to characteristic of batch equipment, in zone units, reduce a state space and an action space of a reinforcement learning model based on the grouping, re-train the reinforcement learning model based on the reduced state space and action space, re-execute the optimization algorithm based on the re-trained reinforcement learning model, and select final algorithm based on a result of re-executing the optimization algorithm.

In addition, the processor 820 according to the embodiment may also perform a method of optimizing the processing space allocation of a wafer lot in the batch equipment of the semiconductor manufacturing process described above with reference to FIG. 9.

While the disclosure has been particularly shown and described with reference to example embodiments thereof. it will be understood that various change in form and details may be made therein without departing from the spirit and scope of the following claims.

What is claimed is:

1. A method of optimizing a slot allocation of a wafer in a batch equipment of a semiconductor manufacturing process, the method comprising:
loading wafer-specific characteristic data and slot allocation history data;
training a reinforcement learning model by using the wafer-specific characteristic data and the slot allocation history data;
executing an optimization algorithm for determining a wafer-specific optimum slot location, based on the reinforcement learning model;
selecting, based on a time for executing the optimization algorithm satisfying a system requirement time, the optimization algorithm as a final algorithm; and
allocating a wafer-specific slot in the batch equipment in a next process of the semiconductor manufacturing process, by using the final algorithm.

2. The method of claim 1, further comprising,
based on the time for executing the optimization algorithm not satisfying the system requirement time, grouping, in zone units, slots having similar process results of wafers according to a characteristic of the batch equipment, and based on the grouped slots, reducing a state space and an action space of the reinforcement learning model,
wherein the final algorithm is selected by performing again the training of the reinforcement learning model and the executing of the optimization algorithm.

3. The method of claim 2, wherein, based on a process result of the wafer having a symmetry in each zone, the reducing the state space and the action space of the reinforcement learning model comprises further reducing the state space and the action space by using the symmetry.

4. The method of claim 1, wherein, in the training the reinforcement learning model, an action of determining slot locations of wafers has a target of minimizing an average defect rate of the wafers.

5. The method of claim 1, wherein, in the training the reinforcement learning model, a reward is defined as a negative value of a defect rate of the wafer according to a slot location of the wafer.

6. The method of claim 1, wherein the optimization algorithm comprises at least one of a genetic algorithm or a greedy algorithm.

7. The method of claim 1, wherein the executing the optimization algorithm comprises:
executing a genetic algorithm; and
based on a time for executing the genetic algorithm not satisfying the system requirement time, executing a greedy algorithm.

8. The method of claim 1, wherein, the allocating the wafer-specific slot comprises allocating one slot to one wafer.

9. The method of claim 1, further comprising storing the trained reinforcement learning model.

10. The method of claim 1, wherein the wafer-specific characteristic data comprises data on a hole profile of the wafer, the data on the hole profile comprising at least one of optical emission spectrometer data, measurement data, or virtual metrology data.

11. A method of optimizing a slot allocation of a wafer in a batch equipment of a semiconductor manufacturing process, the method comprising:
loading wafer-specific characteristic data and slot allocation history data;
grouping, in zone units, slots having similar process results of wafers according to a characteristic of the batch equipment;
training a reinforcement learning model by limiting an action space to a number of slots included in a zone, and by using the wafer-specific characteristic data and the slot allocation history data;
executing an optimization algorithm for determining a wafer-specific optimum slot location, based on the reinforcement learning model;
selecting, based on a time for executing the optimization algorithm satisfying a system requirement time, the optimization algorithm as a final algorithm; and
allocating a wafer-specific slot in the batch equipment in a next operation of the semiconductor manufacturing process, by using the final algorithm.

12. The method of claim 11, wherein, in the training, a reward is defined as a negative value of a defect rate of the wafer according to a slot location of the wafer.

13. The method of claim 11, wherein the optimization algorithm comprises at least one of a genetic algorithm or a greedy algorithm.

14. The method of claim 11, further comprising:
based on the time for executing the optimization algorithm not satisfying the system requirement time, executing another optimization algorithm based on the reinforcement learning model.

15. The method of claim 11, wherein the reinforcement learning model comprises a deep Q-Network model.

16. An electronic device comprising:
a memory storing at least one instruction; and
at least one processor configured to execute the at least one instruction stored in the memory to perform:
train a reinforcement learning model by using wafer-specific characteristic data and slot allocation history data;
execute an optimization algorithm for determining a wafer-specific optimum slot location, based on the reinforcement learning model;
select, based on a time for executing the optimization algorithm satisfying a system requirement time, the optimization algorithm as a final algorithm; and
by using the final algorithm, allocate a wafer-specific slot in batch equipment in a next process of a semiconductor manufacturing process.

17. The electronic device of claim 16, wherein the at least one processor is further configured to:
based on the time for executing the optimization algorithm not satisfying the system requirement time, group, in zone units, slots having similar process results of wafers according to a characteristic of the batch equipment, and based on the grouped slots, reduce a state space and an action space of the reinforcement learning model; and
based on the reduced state space and the reduced action space, re-train the reinforcement learning model, and re-execute the optimization algorithm based on the re-trained reinforcement learning model.

18. The electronic device of claim 16, wherein the at least one processor is further configured to train the reinforcement learning model such that an action of determining slot locations of wafers has a target of minimizing an average defect rate of the wafers.

19. The electronic device of claim 16, wherein, in executing the optimization algorithm, the at least one processor is further configured to apply a constraint condition that does not allow a duplication of a slot allocation.

20. The electronic device of claim 16, wherein the optimization algorithm comprises at least one of a genetic algorithm or a greedy algorithm, and
wherein the at least one processor is further configured to select the final algorithm based on a balance between a calculation speed of the optimization algorithm and a fitness of a solution of the optimization algorithm.
